(19) United States
(12) Patent Application Publication
(10) Pub. No.: US 2012/0032140 A1
(43) Pub. Date: Feb. 9, 2012

(54) LIGHT-EMITTING DIODE INCLUDING A METAL-DIELECTRIC-METAL STRUCTURE

(76) Inventors: Jingjing Li, Palo Alto, CA (US); David A. Fattal, Mountain View, CA (US); Lars Helge Thylen, Huddinge (SE); Michael Renne Ty Tan, Menlo Park, CA (US); Shih-Yuan Wang, Palo Alto, CA (US)

(21) Appl. No.: 13/259,444

(22) PCT Filed: Sep. 18, 2009
(86) PCT No.: PCT/US09/57545

§ 371 Date: Sep. 23, 2011

(51) Int. Cl. H01L 33/04; H01L 33/62

(52) U.S. Cl. 257/13; 257/99; 257/101; 257/E33.066; 257/E33.007

(57) ABSTRACT

A light-emitting diode (LED) (101). The LED (101) includes a plurality of portions including a p-doped portion (112), an intrinsic portion (114), and a n-doped portion (116). The intrinsic portion (114) is disposed between the p-doped portion (112) and the n-doped portion (116) and forms a p-i junction (130) and an i-n junction (134) The LED (101) also includes a metal-dielectric-metal (MDM) structure (104) including a first metal layer (140), a second metal layer (144), and a dielectric medium disposed between the first metal layer (140) and the second metal layer (144). The metal layers of the MDM structure (104) are disposed about orthogonally to the p-i junction (130) and the i-n junction (134); the dielectric medium includes the intrinsic portion (114); and, the MDM structure (104) is configured to enhance modulation frequency of the LED (101) through interaction with surface plasmons that are present in the metal layers.

### TECHNICAL FIELD

Embodiments of the present invention relate generally to the field of light-emitting diodes (LEDs).

### BACKGROUND

The flow and processing of information creates ever increasing demands on the speed with which microelectronic circuitry processes such information. In particular, high speed integrated opto-electronic circuits, as well as means for communicating between electronic devices over communication channels having high-bandwidth and high-frequency, are of critical importance in meeting these demands.

Integrated optics and communication by means of optical channels have attracted the attention of the scientific and technological community to meet these demands. However, to the inventors' knowledge per the current state of the art, excepting embodiments of the present invention, light-emitting diodes (LEDs) used for optical signal generation have an upper modulation frequency of about 4 gigahertz (GHz) at a −3 decibel (dB) roll-off point, which limits the bandwidth and information carrying capacity of opto-electronic devices utilizing LEDs as a source for the optical signal. Scientists engaged in the development of integrated optical circuits and communication by means of optical channels are keenly interested in finding a means for increasing the bandwidth and information carrying capacity of opto-electronic devices utilizing LEDs. Thus, research scientists are actively pursuing new approaches for meeting these demands.

### DESCRIPTION OF THE DRAWINGS

The accompanying drawings, which are incorporated in and form a part of this specification, illustrate embodiments of the technology and, together with the description, serve to explain the embodiments of the technology:

FIG. 1 is a perspective view of a p-i-n, light-emitting diode (LED) including a metal-dielectric-metal (MDM) structure that is configured to enhance modulation frequency of the LED through interaction with surface plasmons that are present in metal layers of the MDM structure, in accordance with an embodiment of the present invention.

FIG. 2 is a perspective view of the p-i-n, LED including the MDM structure, similar to that of FIG. 1, but further including electrically insulating layers disposed between respective metal layers and a dielectric medium of the MDM structure that are configured to reduce surface recombination to enhance modulation frequency of the LED, in accordance with an embodiment of the present invention.

FIG. 3 is a perspective view of a LED including a MDM structure such that the LED includes a gain medium disposed between a p-doped portion of the LED and a n-doped portion of the LED that is included in the MDM structure, in accordance with an embodiment of the present invention.

FIG. 4 is a perspective view of the LED including the MDM structure, similar to that of FIG. 3, but further including electrically insulating layers disposed between respective metal layers and the dielectric medium of the MDM structure that are configured to reduce surface recombination to enhance modulation frequency of the LED, in accordance with an embodiment of the present invention.

FIG. 5A is a cross-sectional elevation view of a representative gain medium of the LEDs of FIGS. 3 and 4 including a semiconductor quantum-dot structure such that the semiconductor quantum-dot structure includes a plurality of islands of a first compound semiconductor surrounded by an overlayer of a second compound semiconductor, in accordance with an embodiment of the present invention.

FIG. 5B is a cross-sectional elevation view of an alternative gain medium for the LEDs of FIGS. 3 and 4 including a colloidal quantum-dot structure such that the colloidal quantum-dot structure includes a plurality of nanoparticles dispersed in a dielectric matrix, in accordance with an embodiment of the present invention.

FIG. 5C is a cross-sectional elevation view of another alternative gain medium for the LEDs of FIGS. 3 and 4 including a semiconductor quantum-well (QW) structure such that the semiconductor QW structure includes a multilayer including a plurality of bilayers of compound semiconductors, in accordance with an embodiment of the present invention.

The drawings referred to in this description should not be understood as being drawn to scale except if specifically noted.

### DESCRIPTION OF EMBODIMENTS

Reference will now be made in detail to the alternative embodiments of the present invention. While the invention will be described in conjunction with the alternative embodiments, it will be understood that they are not intended to limit the invention to these embodiments. On the contrary, the invention is intended to cover alternatives, modifications and equivalents, which may be included within the spirit and scope of the invention as defined by the appended claims.

Furthermore, in the following description of embodiments of the present invention, numerous specific details are set forth in order to provide a thorough understanding of the present invention. However, it should be noted that embodiments of the present invention may be practiced without these specific details. In other instances, well known methods, procedures, and components have not been described in detail as not to unnecessarily obscure embodiments of the present invention. Throughout the drawings, like components are denoted by like reference numerals, and repetitive descriptions are omitted for clarity of explanation if not necessary.

Embodiments of the present invention include a light-emitting diode (LED). The LED includes a plurality of portions including a p-doped portion of a semiconductor, an intrinsic portion of the semiconductor, and a n-doped portion of the semiconductor. The intrinsic portion is disposed between the p-doped portion and the n-doped portion and forms a p-i junction with the p-doped portion and an i-n junction with the n-doped portion. The LED also includes a metal-dielectric-metal (MDM) structure including a first metal layer, a second metal layer, and a dielectric medium disposed between the first metal layer and the second metal layer. The metal layers of the MDM structure are disposed about orthogonally to the p-i junction and the i-n junction; the dielectric medium includes the intrinsic portion; and, the MDM structure is configured to enhance modulation frequency of the LED through interaction with surface plasmons that are present in the first metal layer and the second metal layer. As used herein, the term of art, “dielectric medium,” refers to a material having a real component of an index of refraction of between about 1 and 5, and may include the p-doped, the intrinsic, and the n-doped portion of the semiconductor.

Embodiments of the present invention are directed to a LED of very fast speed, with a modulation frequency up to about 800 gigahertz (GHz) for useful modulation frequencies, in one embodiment of the present invention. As used herein, the phrase, “useful modulation frequencies,” means frequencies for which adequate power is emitted to give a useable signal to noise ratio (SNR) at a receiver. The operation speed of a LED is often limited by the spontaneous emission rate. In embodiments of the present invention, by providing an LED including a MDM structure, the emission rate is greatly enhanced because of the surface plasmon. The MDM structure gives a well-confined surface plasmon polariton, and the mode shape of the surface plasmon polariton overlaps well with a gain medium, which may include semiconductor portions. This ensures good coupling between the spontaneous emission and the surface plasmon polariton, thus, a fast modulation speed of the LED. In one embodiment of the present invention, the MDM structure provides one difference from the existing surface plasmon assisted LED technology. Thus, in embodiments of the present invention, the emission rate can be very high, so that the speed of the LED including the MDM structure can be very fast compared with LEDs of previous technology, which have, to the inventors' knowledge, an upper modulation frequency of about 4 GHz at the −3 decibel (dB) roll-off point, which is less than the upper modulation frequency expected for embodiments of the present invention. For example, LEDs of previous technology have bandwidths such that the upper limit of the bandwidth is given by an upper modulation frequency of less than about 4 GHz, which means from about 10 megahertz (MHz) to about 4 GHz the amplitude rolls off by −3 dB. For embodiments of the present invention, LEDs including the MDM have bandwidths such that the upper limit of the bandwidth is given by an upper modulation frequency of in excess of 100 GHz, which means from about 10 MHz to greater than 100 GHz, up to as much as about 800 GHz depending on design considerations which are subsequently described, for useful modulation frequencies. In another embodiment of the present invention, by adding an electrically insulating layer between the dielectric medium, which includes a gain medium of the LED, and the metal layers of the MDM structure, the non-radiative recombination on the metal surface, which is very common in metal-assisted LEDs, can be greatly reduced. In other embodiments of the present invention, the gain medium of the LED may include, by way of example without limitation thereto, the following alternative structures: various types of quantum dot structures, a semiconductor quantum-well (QW), and impurity doped crystals, such as N vacancies in diamond. Moreover, although a gain medium is usually not referred to as a dielectric medium, as used herein in later discussion of the gain medium, the use of the term of art, “dielectric medium,” with respect to the gain medium is used in light of the optical properties associated with the dielectric medium as described above in terms of the index of refraction of the dielectric medium, and the index of refraction of a gain medium included in the dielectric medium. In another embodiment of the present invention, the MDM structure may be pumped electrically through a p-i-n junction structure. Thus, in accordance with embodiments of the present invention, the MDM structure supports a surface plasmon polariton that provides a strong emission rate, while the electrically insulating layer between the metal and the gain medium reduces the non-radiative recombination at the metal surface.

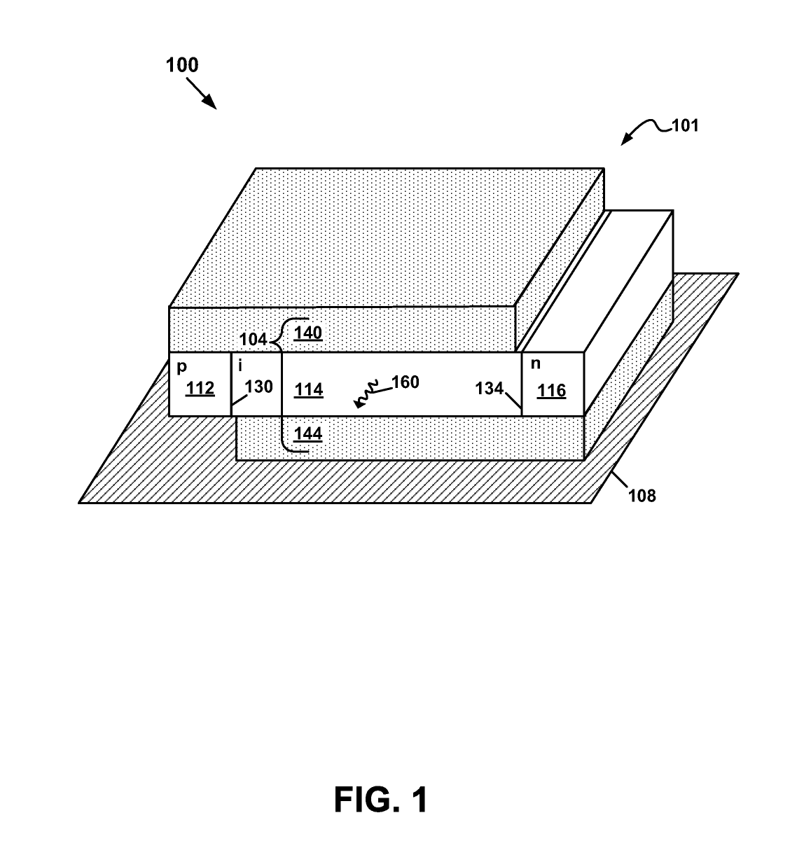

Embodiments of the present invention also include environments in which the LEDs including the MDM structure may be included. For example without limitation thereto, in accordance with embodiments of the present invention, a fiber optic communication device including the LED including the MDM structure as an optical-signal output driver is within the spirit and scope of embodiments of the present invention. By way of further example without limitation thereto, in accordance with embodiments of the present invention, an integrated-optics device including the LED including the MDM structure as an on-chip optical-signal generator is also within the spirit and scope of embodiments of the present invention. Moreover, embodiments of the present invention that include environments, in which the LEDs including the MDM structure may be included, are various environments in integrated optics and optical communication, such as fiber-optic communication, in which the LEDs including the MDM structure, which are subsequently described in FIGS. 1-5C, may find application.

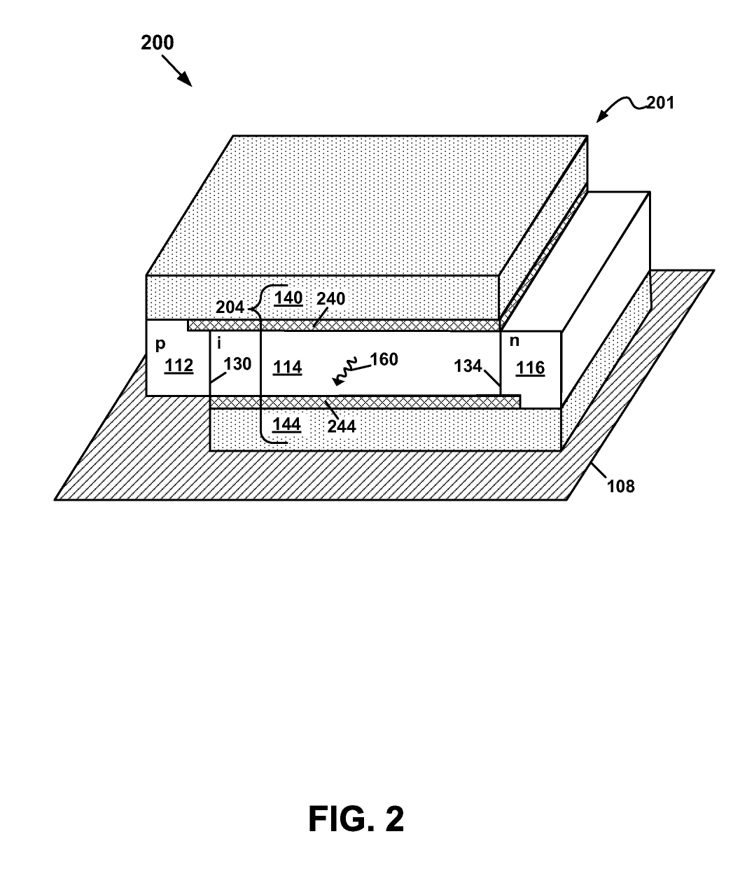

With reference now to FIG. 1, in accordance with embodiments of the present invention, a perspective view 100 of a p-i-n, LED 101 including a MDM structure 104 is shown. The MDM structure 104 is configured to enhance modulation frequency of the LED 101 through interaction with surface plasmons that are present between metal layers 140 and 144 of the MDM structure 104. The LED 101 includes a plurality of portions that includes a p-doped portion 112 of a semiconductor, an intrinsic portion 114 of the semiconductor, and a n-doped portion 116 of the semiconductor. The intrinsic portion 114 is disposed between the p-doped portion 112 and the n-doped portion 116 and forms a p-i junction 130 with the p-doped portion 112 and an i-n junction 134 with the n-doped portion 116. LED 101 also includes a MDM structure 104. The MDM structure 104 includes a first metal layer 140, a second metal layer 144 and a dielectric medium disposed between the first metal layer 140 and the second metal layer 144. In accordance with embodiments of the present invention, the metal layers 140 and 144 of the MDM structure 104 are disposed about orthogonally to the p-i junction 130 and the i-n junction 134; the dielectric medium includes the intrinsic portion 114; and, the MDM structure 104 is configured to enhance modulation frequency of the LED 101 through interaction with surface plasmons that are present in the first metal layer 140 and the second metal layer 144. In accordance with embodiments of the present invention, as shown in FIG. 1 as well as subsequent FIGS. 2-4, LEDs including the MDM structure are shown, by way of example without limitation thereto, as being arranged with the planes of the metal layers 140 and 144 of the MDM structure parallel to a substrate 108, which is referred to herein as the lateral configuration. However, in accordance with other embodiments of the present invention, LEDs including the MDM structures of FIGS. 1-4 that are arranged with the planes of the metal layers 140 and 144 of the MDM structure perpendicular to the substrate 108, which is referred to herein as the vertical configuration (not shown), are also within the spirit and scope of embodiments of the present invention

With further reference to FIG. 1, in accordance with an embodiment of the present invention, the semiconductor used in the LED 101 including MDM structure 104 may be selected from the group consisting of silicon, indium arsenide (InAs), gallium phosphide (GaP) and gallium arsenide (GaAs), by way of example without limitation thereto, as the use of other semiconductors, and in particular compound semiconductors, is within the spirit and scope of embodiments of the present invention. In one embodiment of the present invention, the LED 101 is configured to emit electromagnetic radiation 160 with a wavelength between about 400 nanometers (nm) and about 2 micrometers (μm). In another embodiment of the present invention, the LED 101 is configured to emit electromagnetic radiation 160 with a wavelength of about 1550 nm. In accordance with embodiments of the present invention, the LED 101 including MDM structure 104 is also configured to modulate the emitted electromagnetic radiation 160 at frequencies up to about 800 GHz for useful modulation frequencies. However, in embodiments of the present invention, the LED 101 including MDM structure 104 that is configured to modulate the emitted electromagnetic radiation 160 at the high frequency of 800 GHz for useful modulation frequencies is expected to operate with lesser efficiency than a LED 101 including MDM structure 104 that is configured to modulate the emitted electromagnetic radiation 160 at a frequency of, for example, 200 GHz for useful modulation frequencies. In accordance with embodiments of the present invention, the election of a particular frequency-efficiency combination lies within the discretion of the device designer depending on a particular application for the LED including MDM structure, as there exists a trade-off between the use of high frequency and the attainment of high efficiency. In one embodiment of the present invention, the thickness of the intrinsic portion 114 of LED 101 may be less than or equal to about 100 nm. In another embodiment of the present invention, the distance between the between the p-doped portion 112 and the n-doped portion 116, which is the length of the intrinsic portion 114 of LED 101, may be between about 100 nm and about 50 μm.

With further reference to FIG. 1, in accordance with an embodiment of the present invention, the first metal of the first metal layer 140 of the MDM structure 104 may be selected from the group consisting of silver, gold, copper and aluminum, by way of example without limitation thereto; and, the second metal of the second metal layer 144 of the MDM structure 104 may also be selected from the group consisting of silver, gold, copper and aluminum, by way of example without limitation thereto. In accordance with embodiments of the present invention, various other metals that can produce surface plasmons may be used; for example, the first metal of the first metal layer 140 of the MDM structure 104 may be selected from the group further consisting of titanium and chromium, and the second metal of the second metal layer 144 of the MDM structure 104 may also be selected from the group further consisting of titanium and chromium. In accordance with embodiments of the present invention, by way of example without limitation thereto, the thickness of the first metal layer 140 of the MDM structure 104 may be between 10 nm and 500 nm; and, the thickness of the second metal layer 144 of the MDM structure 104 may also be between 10 nm and 500 nm.

With reference now to FIG. 2, in accordance with embodiments of the present invention, a perspective view 200 of a p-i-n, LED 201 including an alternative MDM structure 204 is shown. The p-i-n, LED 201 including the alternative MDM structure 204 is similar to the p-i-n, LED 101 of FIG. 1; but, the MDM structure 204 further includes electrically insulating layers 240 and 244 disposed between respective metal layers 140 and 144 and the dielectric medium of the MDM structure 204. In accordance with embodiments of the present invention, the electrically insulating layers 240 and 244 are configured to reduce surface recombination to enhance modulation frequency of the LED 201. In an embodiment of the present invention, the first electrically insulating layer 240 includes a material selected from the group consisting of silicon dioxide (SiO₂) and alumina (Al₂O₃). In another embodiment of the present invention, the second electrically insulating layer 244 may also include a material selected from the group consisting of SiO₂ and Al₂O₃. The electrically insulating layers 240 and 244 may be fabricated by various thin-film deposition techniques, known in the art, such as sputtering, or alternatively, chemical-vapor deposition (CVD). In an embodiment of the present invention, the MDM structure 204 further includes a first electrically insulating layer 240 and a second electrically insulating layer 244. In an embodiment of the present invention, the first electrically insulating layer 240 is disposed between the first metal layer 140 and the dielectric medium including the intrinsic portion 114; and, the second electrically insulating layer 244 is disposed between the second metal layer 144 and the dielectric medium including the intrinsic portion 114. As described herein, the above-described embodiments of the present invention with respect to the p-i-n, LED 101 are included, as applicable, within embodiments of the present invention with respect to the p-i-n, LED 201.

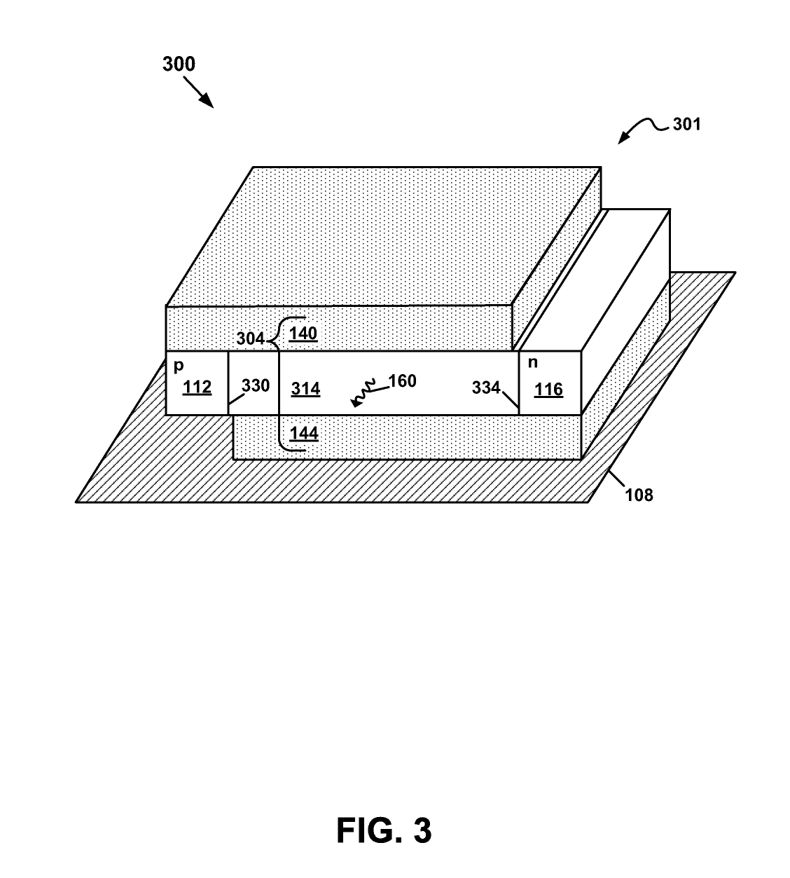

With reference now to FIG. 3, in accordance with embodiments of the present invention, a perspective view 300 of a LED 301 including a MDM structure 304 is shown in which the LED 301 includes a gain medium 314 disposed between a p-doped portion 112 of the LED 301 and a n-doped portion 116 of the LED 301. Moreover, in accordance with an embodiment of the present invention, the dielectric medium of the MDM structure 304 includes the gain medium 314 of the LED 301. The LED 301 includes a plurality of portions that includes a p-doped portion 112 of a semiconductor, a gain medium 314, and a n-doped portion 116 of the semiconductor. The gain medium 314 is disposed between the p-doped portion 112 and the n-doped portion 116 and forms a first junction 330 with the p-doped portion 112 and a second junction 334 with the n-doped portion 116. LED 301 also includes a MDM structure 304. The MDM structure 304 includes a first metal layer 140, a second metal layer 144 and a dielectric medium disposed between the first metal layer 140 and the second metal layer 144. In accordance with embodiments of the present invention, the metal layers 140 and 144 of the MDM structure 304 are disposed about orthogonally to the first junction 330 and the second junction 334; the dielectric medium includes the gain medium 314; and, the MDM structure 304 is configured to enhance modulation frequency of the LED 301 through interaction with surface plasmons that are present in the first metal layer 140 and the second metal layer 144.

With further reference to FIG. 3, in accordance with an embodiment of the present invention, the semiconductor used in the LED 301 including MDM structure 304 may be selected from the group consisting of silicon, InAs, GaP and GaAs, by way of example without limitation thereto, as the use of other semiconductors, and in particular compound semiconductors, is within the spirit and scope of embodiments of the present invention. In one embodiment of the present invention, the LED 301 is configured to emit electromagnetic radiation 160 with a wavelength between about 400 nm and about 2 μm. In another embodiment of the present invention, the LED 301 is configured to emit electromagnetic radiation 160 with a wavelength of about 1550 nm. In accordance with embodiments of the present invention, the LED 301 including MDM structure 304 is also configured to modulate the emitted electromagnetic radiation 160 at frequencies up to about 800 GHz for useful modulation frequencies. However, in embodiments of the present invention, the LED 301 including MDM structure 304 that is configured to modulate the emitted electromagnetic radiation 160 at the high frequency of 800 GHz for useful modulation frequencies is expected to operate with lesser efficiency than a LED 301 including MDM structure 304 that is configured to modulate the emitted electromagnetic radiation 160 at a frequency of, for example, 200 GHz for useful modulation frequencies. In accordance with embodiments of the present invention, the election of a particular frequency-efficiency combination lies within the discretion of the device designer depending on a particular application for the LED including MDM structure, as there exists a trade-off between the use of high frequency and the attainment of high efficiency. In one embodiment of the present invention, the thickness of the gain medium 314 of LED 301 may be less than or equal to about 100 nm. In another embodiment of the present invention, the distance between the between the p-doped portion 112 and the n-doped portion 116, which is the length of the gain medium 314, may be between about 100 nm and about 50 μm.

With further reference to FIG. 3, in accordance with an embodiment of the present invention, the first metal of the first metal layer 140 of the MDM structure 304 may be selected from the group consisting of silver, gold, copper and aluminum, by way of example without limitation thereto; and, the second metal of the second metal layer 144 of the MDM structure 304 may also be selected from the group consisting of silver, gold, copper and aluminum, by way of example without limitation thereto. In accordance with embodiments of the present invention, various other metals that can produce surface plasmons may be used; for example, the first metal of the first metal layer 140 of the MDM structure 304 may be selected from the group further consisting of titanium and chromium, and the second metal of the second metal layer 144 of the MDM structure 304 may also be selected from the group further consisting of titanium and chromium. In accordance with embodiments of the present invention, by way of example without limitation thereto, the thickness of the first metal layer 140 of the MDM structure 304 may be between 10 nm and 500 nm; and, the thickness of the second metal layer 144 of the MDM structure 304 may also be between 10 nm and 500 nm.

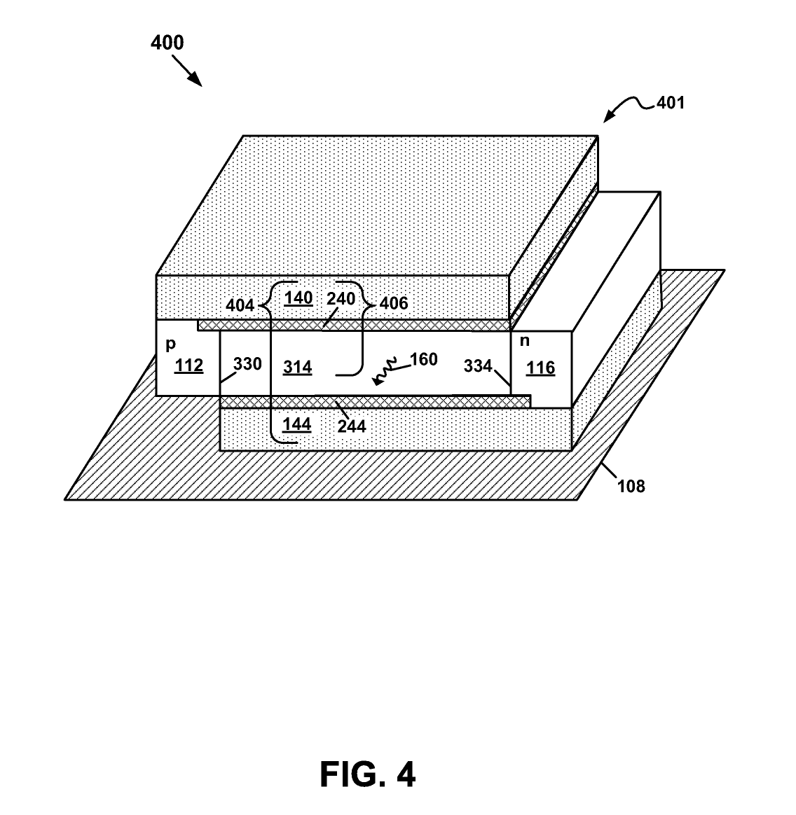

With reference now to FIG. 4, in accordance with embodiments of the present invention, a perspective view 400 of a LED 401 including an alternative MDM structure 404 is shown. The LED 401 including the alternative MDM structure 404 is similar to the LED 301 of FIG. 3; but, the MDM structure 404 further includes electrically insulating layers 240 and 244 disposed between respective metal layers 140 and 144 and the dielectric medium of the MDM structure 404. In accordance with embodiments of the present invention, the electrically insulating layers 240 and 244 are configured to reduce surface recombination to enhance modulation frequency of the LED 401. In an embodiment of the present invention, the first electrically insulating layer 240 includes a material selected from the group consisting of SiO₂ and Al₂O₃. In another embodiment of the present invention, the second electrically insulating layer 244 may also include a material selected from the group consisting of SiO₂ and alumina Al₂O₃. The electrically insulating layers 240 and 244 may be fabricated by various thin-film deposition techniques, known in the art, such as sputtering, or alternatively, CVD. In an embodiment of the present invention, the MDM structure 404 further includes a first electrically insulating layer 240 and a second electrically insulating layer 244. In an embodiment of the present invention, the first electrically insulating layer 240 is disposed between the first metal layer 140 and the dielectric medium including the gain medium 314; and, the second electrically insulating layer 244 is disposed between the second metal layer 144 and the dielectric medium including the gain medium 314.

With further reference to FIG. 4, in accordance with embodiments of the present invention, the LED 401 includes a plurality of portions that includes a p-doped portion 112 of a semiconductor, a gain medium 314, and a n-doped portion 116 of the semiconductor. The gain medium 314 is disposed between the p-doped portion 112 and the n-doped portion 116 and forms a first junction 330 with the p-doped portion 112 and a second junction 334 with the n-doped portion 116. LED 401 also includes a metal-insulator-dielectric MID structure 406. The MID structure 406 includes at least a first metal layer 140, a dielectric medium, and at least a first electrically insulating layer 240 disposed between the first metal layer 140 and the dielectric medium. In accordance with embodiments of the present invention, at least the first metal layer 140 of the MID structure 406 is disposed about orthogonally to the first junction 330 and the second junction 334; the dielectric medium includes the gain medium 314; the first electrically insulating layer 240 is configured to reduce surface recombination to enhance modulation frequency of the LED 401; and, the MID structure 406 is configured to enhance modulation frequency of the LED 401 through interaction with surface plasmons that are present in at least the first metal layer 140. As described herein, the above-described embodiments of the present invention with respect to the LED 301 are included, as applicable, within embodiments of the present invention with respect to the LED 401.

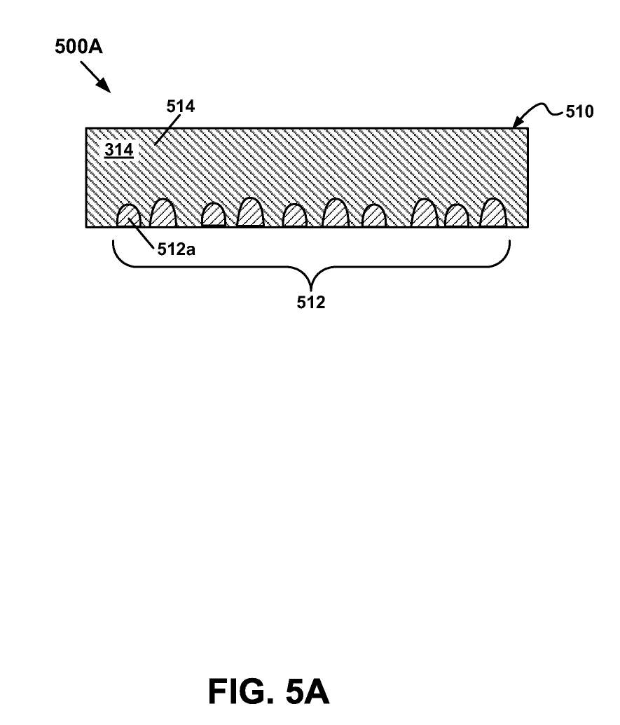

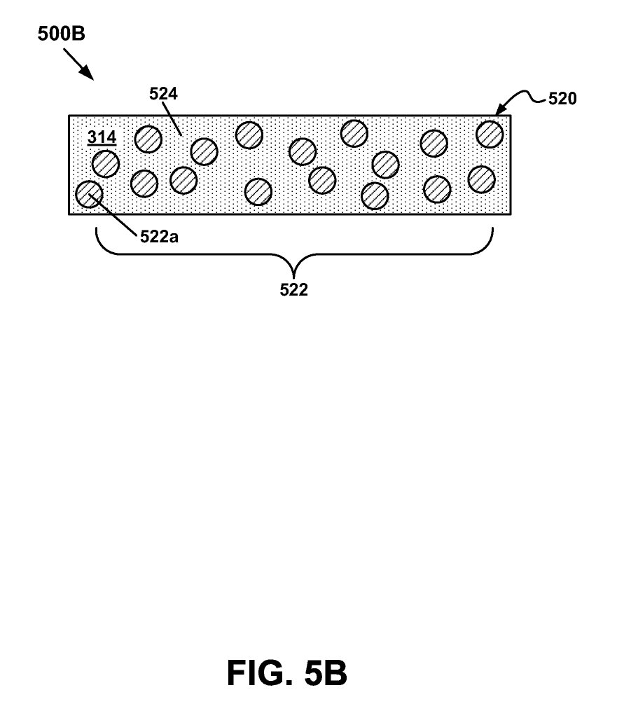

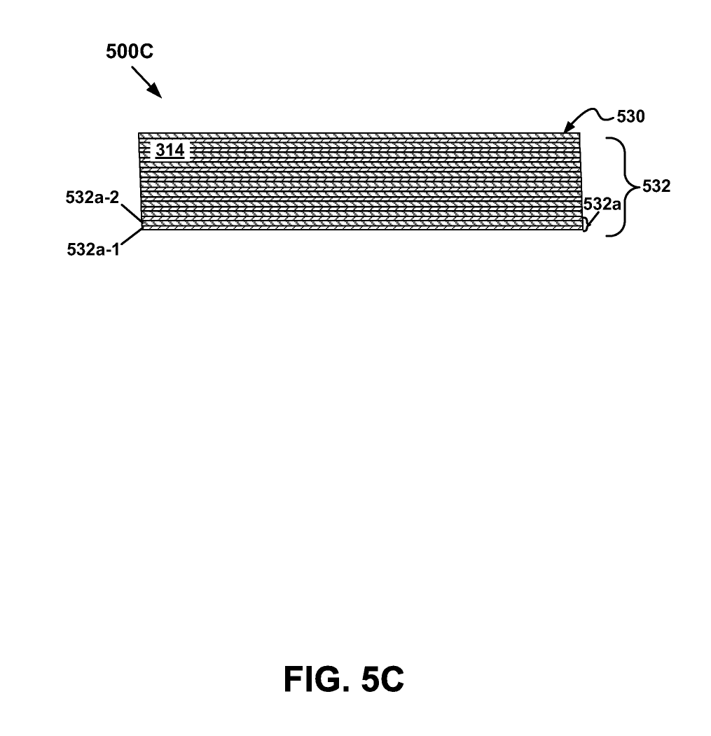

With reference now to FIG. 5A, in accordance with embodiments of the present invention, a cross-sectional elevation view 500A of a representative gain medium 314 of the LEDs 301 and 401 of respective FIGS. 3 and 4 is shown. In an embodiment of the present invention, the gain medium 314 includes a semiconductor quantum-dot structure 510 such that the semiconductor quantum-dot structure 510 includes a plurality 512 of islands, of which island 512a is an example, of a first compound semiconductor surrounded by an overlayer 514 of a second compound semiconductor. In one embodiment of the present invention, the first compound semiconductor of the plurality 512 of islands, of which island 512a is an example, includes InAs and the second compound semiconductor includes GaAs. In embodiments of the present invention, the plurality 512 of islands, of which island 512a is an example, of the first compound semiconductor may be fabricated by various thin-film deposition techniques, known in the art, such as sputtering, or alternatively, molecular-beam epitaxy (MBE), or alternatively, metalorganic CVD (MOCVD). In embodiments of the present invention, the thin-film deposition processes used to fabricate the plurality 512 of islands, of which island 512a is an example, are controlled to produce a plurality 512 of islands that are epitaxially matched with the underlying substrate (not shown) upon which the plurality 512 of islands are grown; and, the amount of material deposited is controlled to prevent coalescence of the deposited material into a continuous layer. Similarly, in embodiments of the present invention, the overlayer 514 of the second compound semiconductor is also deposited using thin-film deposition processes such as sputtering, or alternatively, molecular-beam epitaxy (MBE), or alternatively, metalorganic CVD (MOCVD). Similar, procedures used to control the epitaxial growth of the plurality 512 of islands of the first compound semiconductor, which are known in the art, may be used to grow the overlayer 514 of the second compound semiconductor, but the conditions may be altered to assure the growth of a relatively flat and continuous layer.

With reference now to FIG. 5B, in accordance with embodiments of the present invention, a cross-sectional elevation view 500B of an alternative gain medium 314 of the LEDs 301 and 401 of respective FIGS. 3 and 4 is shown. In an embodiment of the present invention, the gain medium 314 includes a colloidal quantum-dot structure 520 such that the colloidal quantum-dot structure 520 includes a plurality 522 of nanoparticles, of which nanoparticle 522a is an example, dispersed in a dielectric matrix 524. In accordance with embodiments of the present invention, the nanoparticles may include a material selected from the group consisting of silicon, InAs, GaP, GaAs, cadmium selenide (CdSe) and cadmium telluride (CdTe) by way of example without limitation thereto, as the use of other materials, and in particular compound semiconductors, is within the spirit and scope of embodiments of the present invention. In an embodiment of the present invention, the dielectric matrix may include an organic polymer, such as photoresist.

With reference now to FIG. 5C, in accordance with embodiments of the present invention, a cross-sectional elevation view of another alternative gain medium 314 of the LEDs 301 and 401 of respective FIGS. 3 and 4 is shown. In an embodiment of the present invention, the gain medium 314 includes a semiconductor quantum-well (QW) structure 530 such that the semiconductor QW structure 530 includes a multilayer including a plurality 532 of bilayers, of which bilayer 532a is an example, of compound semiconductors. In an embodiment of the present invention, the semiconductor QW structure 530 includes bilayers of GaP and GaAs with a repetition of between 10 to 100 periods. In an embodiment of the present invention, a thickness of a GaP layer 532a-1 of the bilayer 532a may be between about 1 nm and about 10 nm, and a thickness of a GaAs layer 532a-2 of the bilayer 532a may be between about 1 nm and about 10 nm.

The foregoing descriptions of specific embodiments of the present invention have been presented for purposes of illustration and description. They are not intended to be exhaustive or to limit the invention to the precise forms disclosed, and many modifications and variations are possible in light of the above teaching. The embodiments described herein were chosen and described in order to best explain the principles of the invention and its practical application, to thereby enable others skilled in the art to best utilize the invention and various embodiments with various modifications as are suited to the particular use contemplated. It is intended that the scope of the invention be defined by the claims appended hereto and their equivalents.

What is claimed is:

1. A light-emitting diode (101) comprising:
a plurality of portions comprising:
a p-doped portion (112) of a semiconductor, an intrinsic portion (114) of said semiconductor, and a n-doped portion (116) of said semiconductor, said intrinsic portion (114) disposed between said p-doped portion (112) and said n-doped portion (116) and forming a p-i junction (130) with said p-doped portion (112) and an i-n junction (134) with said n-doped portion (116); and
a metal-dielectric-metal structure (104) comprising:
a first metal layer (140);
a second metal layer (144); and
a dielectric medium disposed between said first metal layer (140) and said second metal layer (144);
wherein metal layers of said metal-dielectric-metal structure (104) are disposed about orthogonally to said p-i junction (130) and said i-n junction (134), said dielectric medium comprises said intrinsic portion (114), and said metal-dielectric-metal structure (104) is configured to enhance modulation frequency of said light-emitting diode (101) through interaction with surface plasmons that are present in said first metal layer (140) and said second metal layer (144).

2. The light-emitting diode (101) of claim 1, wherein said semiconductor is selected from the group consisting of silicon, indium arsenide, gallium phosphide and gallium arsenide.

3. The light-emitting diode (101) of claim 1, wherein said light-emitting diode (101) is configured to emit electromagnetic radiation (160) with a wavelength between about 400 nm and about 2 μm, and is configured to modulate said electromagnetic radiation (160) at frequencies up to about 800 GHz.

4. The light-emitting diode (101) of claim 1, wherein said first metal of said first metal layer (140) is selected from the group consisting of silver, gold, copper and aluminum, and said second metal of said second metal layer (144) is selected from the group consisting of silver, gold, copper and aluminum.

5. The light-emitting diode (201) of claim 1, wherein said metal-dielectric-metal structure (204) further comprises:
a first electrically insulating layer (240); and
a second electrically insulating layer (244);
wherein said first electrically insulating layer (240) is disposed between said first metal layer (140) and said dielectric medium comprising said intrinsic portion (114), and said second electrically insulating layer (244) is disposed between said second metal layer (144) and said dielectric medium comprising said intrinsic portion (114).

6. A light-emitting diode (301), comprising:
a plurality of portions comprising:
a p-doped portion (112) of a semiconductor, a gain medium (314), and a n-doped portion (116) of a semiconductor, said gain medium (314) disposed between said p-doped portion (112) and said n-doped portion (116) and forming a first junction (330) with said p-doped portion (112) and a second junction (334) with said n-doped portion (116); and
a metal-dielectric-metal structure (304) comprising:
a first metal layer (140);
a second metal layer (144); and
a dielectric medium disposed between said first metal layer (140) and said second metal layer (144);
wherein metal layers of said metal-dielectric-metal structure (304) are disposed about orthogonally to said first junction (330) and said second junction (334), said dielectric medium comprises said gain medium (314), and said metal-dielectric-metal structure (304) is configured to enhance modulation frequency of said light-emitting diode (301) through interaction with surface plasmons that are present in said first metal layer (140) and said second metal layer (144).

7. The light-emitting diode (301) of claim 6, wherein said first metal of said first metal layer (140) is selected from the group consisting of silver, gold, copper and aluminum, and said second metal of said second metal layer (144) is selected from the group consisting of silver, gold, copper and aluminum.

8. The light-emitting diode (401) of claim 6, wherein said metal-dielectric-metal structure (204) further comprises:
a first electrically insulating layer (240); and
a second electrically insulating layer (244);
wherein said first electrically insulating layer (240) is disposed between said first metal layer (140) and said dielectric medium comprising said gain medium (314), and said second electrically insulating layer (244) is disposed between said second metal layer (144) and said dielectric medium comprising said gain medium (314).

9. The light-emitting diode (301) of claim 6, wherein said gain medium (314) comprises a semiconductor quantum-dot structure.

10. The light-emitting diode (301) of claim 9, wherein said semiconductor quantum-dot structure (510) comprises a plurality (512) of islands of a first compound semiconductor surrounded by an overlayer (514) of a second compound semiconductor.

11. The light-emitting diode (301) of claim 10, wherein said first compound semiconductor of said plurality (512) of islands comprises indium arsenide and said second compound semiconductor of said overlayer (514) comprises gallium arsenide.

12. The light-emitting diode (301) of claim 6, wherein said gain medium (314) comprises a colloidal quantum-dot structure (520) comprising a plurality (522) of nanoparticles dispersed in a dielectric matrix (524).

13. The light-emitting diode (301) of claim 6, wherein said gain medium (314) comprises a semiconductor quantum-well structure (530).

14. The light-emitting diode (301) of claim 13, wherein said semiconductor quantum-well structure (530) comprises a multilayer comprising a plurality (532) of bilayers of gallium phosphide and gallium arsenide with a repetition of between 10 to 100 periods; and
wherein a thickness of a gallium phosphide layer (532a-1) of a bilayer (532a) is between about 1 nm and about 10 nm, and a thickness of a gallium arsenide layer (532a-2) of said bilayer (532a) is between about 1 nm and about 10 nm.

15. A light-emitting diode (401), comprising:
a plurality of portions comprising:
a p-doped portion (112) of a semiconductor, a gain medium (314), and a n-doped portion (116) of a semiconductor, said gain medium (314) disposed between said p-doped portion (112) and said n-doped portion (116) and forming a first junction (330) with said p-doped portion (112) and a second junction (334) with said n-doped portion (116); and
a metal-insulator-dielectric structure (406) comprising:
at least a first metal layer (140);
a dielectric medium; and
at least a first electrically insulating layer (240) disposed between said first metal layer (140) and said dielectric medium;
wherein at least said first metal layer (140) of said metal-insulator-dielectric structure (406) is disposed about orthogonally to said first junction (330) and said second junction (334), said dielectric medium comprises said gain medium (314), said first electrically insulating layer (240) is configured to reduce surface recombination to enhance modulation frequency of said light-emitting diode (401) and said metal-insulator-dielectric structure (406) is configured to enhance modulation frequency of said light-emitting diode (401) through interaction with surface plasmons that are present in at least said first metal layer (140).
